(19) United States
(12) Patent Application Publication
(10) Pub. No.: US 2024/0206293 A1
(43) Pub. Date: Jun. 20, 2024

(54) ORGANIC LIGHT-EMITTING DIODE DISPLAY DEVICE

(71) Applicant: LG Display Co., Ltd., Seoul (KR)

(72) Inventors: Joon-Soo HAN, Paju-si (KR); Dae-Hyun KIM, Paju-si (KR); Jae-Sung HU, Paju-si (KR)

(73) Assignee: LG Display Co., Ltd., Seoul (KR)

(21) Appl. No.: 18/528,487

(22) Filed: Dec. 4, 2023

(30) Foreign Application Priority Data
Dec. 20, 2022 (KR) 10-2022-0179768

(51) Int. Cl. H10K 59/80; H10K 59/124

(52) U.S. Cl. CPC H10K 59/879; H10K 59/124

(57) ABSTRACT

An organic light-emitting diode display device can include a plurality of sub-pixels disposed over a substrate where each sub-pixel has an emission area and a non-emission area, a thin film transistor in the non-emission area of each sub-pixel, and an overcoat layer over the thin film transistor in each sub-pixel and including a plurality of micro lenses in the emission area of each sub-pixel. The organic light-emitting diode display device can further include a light-emitting diode in the emission area of each sub-pixel over the overcoat layer and connected to the corresponding thin film transistor. For one sub-pixel among the plurality of sub-pixels, the emission area of the one sub-pixel has at least one flat portion disposed at the overcoat layer where a top surface of the overcoat layer is flat, and the overcoat layer has at least one lens pattern in the at least one flat portion.

### CROSS-REFERENCE TO RELATED APPLICATION

The present application claims priority to Korean Patent Application No. 10-2022-0179768 filed in the Republic of Korea on Dec. 20, 2022, the entire contents of which are hereby expressly incorporated by reference into the present application.

### BACKGROUND

### Field of the Disclosure

The present disclosure relates to a display device, and more particularly, to an organic light-emitting diode display device with improved light extraction efficiency.

### Discussion of the Background Art

As the information society progresses, a demand for different types of display devices increases, and flat panel display devices (FPD) such as liquid crystal display devices (LCD) and organic light-emitting diode display devices (OLED) have been developed and applied to various fields.

Among the flat panel display devices, organic light-emitting diode display devices, which are also referred to as organic electroluminescent display devices, emit light due to the radiative recombination of an exciton. The exciton is formed from an electron and a hole by injecting charges into a light-emitting layer between a cathode for injecting the electrons and an anode for injecting the holes in a light-emitting diode.

The organic light-emitting diode display device is self-luminous and can be formed over a flexible substrate, such as plastic. Further, the organic light-emitting diode display device offers various advantages and improved properties. For instance, the organic light-emitting diode display device has an excellent contrast ratio and an ultra-thin thickness, and has a response time of several micro seconds. As such, there are advantages in displaying moving images and videos without delays using the organic light-emitting diode display device.

Additionally, the organic light-emitting diode display device has a wide viewing angle and is stable under low temperatures. Further, since the organic light-emitting diode display device is generally driven by a low voltage of direct current (DC) (e.g., 5V to 15V), it is easy to design and manufacture the driving circuits of the organic light-emitting diode display device.

On the other hand, in the process of light being generated in the light-emitting layer of the organic light-emitting diode display device and passing through various components and then being emitted to the outside, if some of such light is not emitted to the outside due to the total internal reflection at the interface between the components, the light extraction efficiency of the organic light-emitting diode display device can be reduced, which can decrease the luminance and increase the power consumption.

Further, a process of ensuring that the layers in the organic light-emitting diode display device are properly formed would be desirable, so as to increase production efficiency as well as performance yield.

### SUMMARY OF THE DISCLOSURE

Accordingly, the present disclosure is to provide an organic light-emitting diode display device that substantially obviates one or more of the limitations and disadvantages described above and associated with the background art.

More specifically, an object of the present disclosure is to provide an organic light-emitting diode display device with improved light extraction efficiency by having micro lenses.

Another object of the present disclosure is to provide an organic light-emitting diode display device capable of efficiently manufacturing and managing micro lenses.

Additional features and aspects will be set forth in the description that follows, and in part will be apparent from the description, or can be learned by practice of the present disclosure provided herein. Other features and aspects of the inventive concepts can be realized and attained by the structure particularly pointed out in the written description, or derivable therefrom, and the claims hereof as well as the appended drawings.

To achieve these and other aspects of the present disclosure, as embodied and broadly described herein, an organic light-emitting diode display device can include a substrate including a plurality of sub-pixels, each sub-pixel having an emission area and a non-emission area; a thin film transistor in the non-emission area of each sub-pixel; an overcoat layer over the thin film transistors, and including a plurality of micro lenses in the emission area of each sub-pixel; and a light-emitting diode in the emission area of each sub-pixel over the overcoat layer, and connected to the corresponding thin film transistor, wherein for a first sub-pixel among the plurality of sub-pixels, the emission area has at least one flat portion where a top surface of the overcoat layer is flat, and the overcoat layer has at least one lens pattern in the at least one flat portion.

According to another aspect of the present disclosure, a display device includes a plurality of sub-pixels disposed over a substrate, each sub-pixel having an emission area and a non-emission area adjacent to the emission area; an overcoat layer disposed over the substrate, and including a plurality of micro lenses in the emission area of each sub-pixel; and a light-emitting element in the emission area of each sub-pixel and disposed over the plurality of micro lenses, wherein the plurality of micro lenses in the emission area of at least one of the plurality of sub-pixels are rotated.

It is to be understood that both the foregoing general description and the following detailed description are examples and are intended to provide further explanation of the inventive concepts as claimed.

### BRIEF DESCRIPTION OF THE DRAWINGS

The accompanying drawings, which are included to provide a further understanding of the present disclosure and which are incorporated in and constitute a part of this application, illustrate aspects of the disclosure and together with the description serve to explain various principles of the present disclosure.

In the drawings:

FIG. 1 is an example of an equivalent circuit diagram of one sub-pixel of an organic light-emitting diode display device according to an embodiment of the present disclosure;

FIG. 2 is a schematic cross-sectional view of the organic light-emitting diode display device according to the embodiment of the present disclosure;

FIG. 3 is a schematic plan view of an organic light-emitting diode display device according to a first embodiment of the present disclosure;

FIG. 4 is an enlarged plan view of an A1 area of FIG. 3;

FIG. 5 is a cross-sectional view corresponding to line I-I′ of FIG. 3;

FIGS. 6A to 6D are cross-sectional views of an organic light-emitting diode display device for illustrating a process of manufacturing the same according to the first embodiment of the present disclosure;

FIG. 7 is an optical image measured in the process of monitoring micro lenses according to an embodiment of the present disclosure;

FIG. 8 is a schematic plan view of an organic light-emitting diode display device according to a second embodiment of the present disclosure;

FIG. 9 is a schematic plan view of an organic light-emitting diode display device according to a third embodiment of the present disclosure;

FIG. 10 is a schematic plan view of an organic light-emitting diode display device according to a fourth embodiment of the present disclosure;

FIG. 11 is an enlarged plan view of emission areas of respective sub-pixels of FIG. 10; and

FIG. 12 is an enlarged schematic plan view of an organic light-emitting diode display device according to a fifth embodiment of the present disclosure.

### DETAILED DESCRIPTION OF THE EMBODIMENTS

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein or can be briefly discussed.

When terms such as “including,” “having,” “comprising” and the like mentioned in this disclosure are used, other parts can be added unless the term “only” is used herein. Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

Although the terms first, second, and the like are used to describe various components, these components are not substantially limited by these terms. These terms are used only to distinguish one component from another component, and may not define any order or sequence. Therefore, a first component described below can substantially be a second component within the technical spirit of the present disclosure.

Features of various embodiments of the present disclosure can be partially or entirely united or combined with each other, technically various interlocking and driving are possible, and each of the embodiments can be independently implemented with respect to each other or implemented together in a related relationship. Further, some features of one embodiment can be applied to another embodiment without a specific description herein, and such applications are part of the present disclosure.

Hereinafter, example embodiments of the present disclosure will be described in detail with reference to accompanying drawings. All the components of each organic light-emitting diode display device according to all embodiments of the present disclosure are operatively coupled and configured. For example, although some components of the organic light-emitting diode display devices may not be specifically described herein, the organic light-emitting diode display devices of the present disclosure include such components to fully and functionally operate.

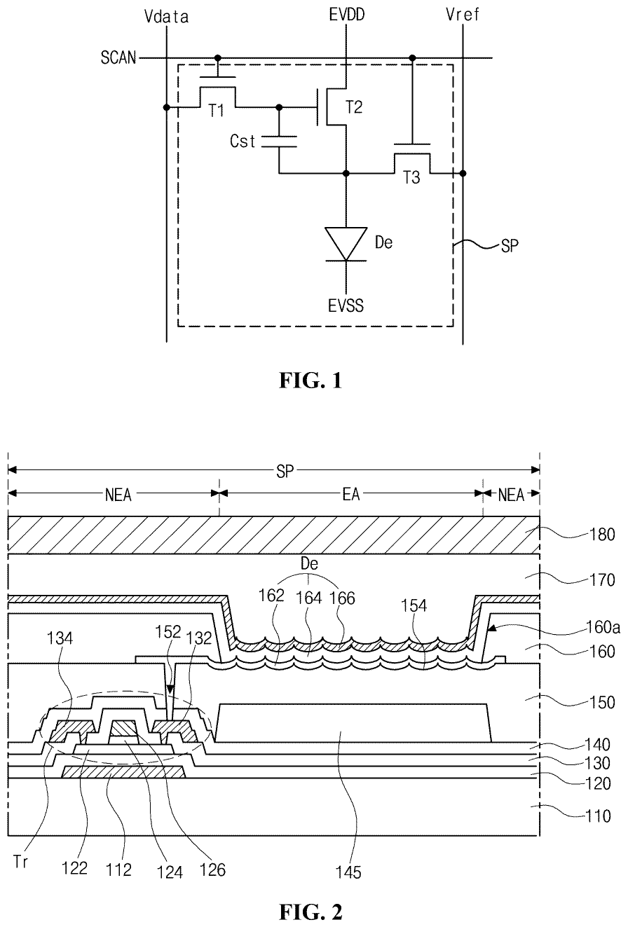

An organic light-emitting diode display device according to embodiments of the present disclosure includes a plurality of pixels arranged in the form of a matrix (or any other form) in a display area, and each pixel includes a plurality of sub-pixels. Each sub-pixel has the same or substantially the same configuration as other sub-pixels. Now, one example of the configuration of such sub-pixel of the organic light-emitting diode display device will be described with reference to FIG. 1 and FIG. 2, but other configurations are possible.

FIG. 1 is an example of an equivalent circuit diagram of one sub-pixel SP of an organic light-emitting diode display device according to an embodiment of the present disclosure.

In FIG. 1, the sub-pixel SP of the organic light-emitting diode display device according to the embodiment of the present disclosure can include first, second, and third transistors T1, T2, and T3, a storage capacitor Cst, and a light-emitting diode De. The first, second, and third transistors T1, T2, and T3 can be a switching transistor T1, a driving transistor T2, and a sensing transistor T3, respectively. The switching transistor T1, the driving transistor T2, and the sensing transistor T3 can be n-type transistors. However, the present disclosure is not limited thereto. Alternatively, the switching transistor T1, the driving transistor T2, and the sensing transistor T3 can be p-type transistors or other types of transistors.

A gate line supplying a scan signal (or gate signal) SCAN and a data line supplying a data signal Vdata can cross each other, and the switching transistor T1 can be disposed at a crossing point of the gate line and the data line. A gate of the switching transistor T1 can be connected to the gate line to receive the gate signal SCAN, and a drain of the switching transistor T1 can be connected to the data line to receive the data signal Vdata.

In addition, a gate of the driving transistor T2 can be connected to a source of the switching transistor T1 and a first capacitor electrode of the storage capacitor Cst. A drain of the driving transistor T2 can be connected to a high potential line supplying a high potential voltage EVDD, and a source of the driving transistor T2 can be connected to an anode of the light-emitting diode De, a second capacitor electrode of the storage capacitor Cst, and a source of the sensing transistor T3.

A gate of the sensing transistor T3 can be connected to the gate line, and a drain of the sensing transistor T3 can be connected to a reference line supplying a reference voltage Vref. Alternatively, the gate of the sensing transistor T3 can be connected to a separate sensing line.

Here, the source and drain locations of each of the transistors T1, T2, and T3 are not limited thereto, and the locations can be interchanged or varied.

Meanwhile, a cathode of the light-emitting diode De can be connected to a low potential line supplying a low potential voltage EVSS. Alternatively, the cathode of the light-emitting diode De can be connected to a ground voltage. As a variation, instead of the light-emitting diode De, another type of light-emitting element can be used.

During an emission period of one frame, the switching transistor T1 can be switched according to the gate signal SCAN transmitted through the gate line to thereby provide the gate of the driving transistor T2 with the data signal Vdata transmitted through the data line. The driving transistor T2 can be switched according to the data signal Vdata to thereby control a current of the light-emitting diode De. In this case, the storage capacitor Cst can maintain charges corresponding to the data signal Vdata for one frame. Accordingly, even if the switching transistor T1 is turned off, the storage capacitor Cst can allow the amount of the current flowing through the light-emitting diode De to be constant and the gray level shown by the light-emitting diode De to be maintained until a next frame.

In addition, one frame can further include a sensing period. During the sensing period, the sensing transistor T3 can be switched according to the gate signal SCAN transmitted through the gate line to thereby provide the source of the driving transistor T2 with the reference voltage Vref. The sensing transistor T3 can detect the voltage change of the source of the driving transistor T2 through the reference line and can calculate the threshold voltage Vth of the driving transistor T2 by comparing the amount of the voltage change with a determination range. Accordingly, by calculating the threshold voltage Vth in real time and compensating for the image data, it is possible to compensate for the change in the characteristics of the driving transistor T2 and prevent image degradation.

FIG. 2 is a schematic cross-sectional view of the organic light-emitting diode display device according to the embodiment of the present disclosure. An example of a cross-section corresponding to one sub-pixel is shown, and a bottom emission-type organic light-emitting diode display device will be described as an example and other variations are possible. The structure shown in FIG. 2 can be applied to any sub-pixel of the present disclosure including FIG. 1, and to any display device of the present disclosure.

In FIG. 2, the organic light-emitting diode display device according to the embodiment of the present disclosure can include a plurality of sub-pixels each having a substrate 110, a thin film transistor Tr, and a light-emitting diode De.

A sub-pixel SP having an emission area EA and a non-emission area NEA can be provided over the substrate 110. The light-emitting diode De can be disposed in the emission area EA, and the thin film transistor Tr can be disposed in the non-emission area NEA.

Specifically, a light-shielding layer 112 can be disposed in the non-emission area NEA over the substrate 110. The substrate 110 can be formed of a transparent insulating material. For example, the substrate 110 can be a glass substrate, a plastic substrate, or any other suitable substrate which can render the organic light-emitting diode display device to be rigid, flexible, bendable, rollable, etc. Polyimide can be used for the plastic substrate, but the embodiments of the present disclosure are not limited thereto.

The light-shielding layer 112 can be formed of at least one of aluminum (Al), copper (Cu), molybdenum (Mo), titanium (Ti), chromium (Cr), nickel (Ni), tungsten (W), or an alloy thereof and can have a single-layer structure or a multi-layer structure. For example, the light-shielding layer 112 can have a double-layer structure including a lower layer of a molybdenum-titanium (MoTi) alloy and an upper layer of copper (Cu), and the upper layer can have a thicker thickness than the lower layer. However, the embodiments of the present disclosure are not limited thereto.

A buffer layer 120 of an insulating material can be placed over the light-shielding layer 112. The buffer layer 120 can be disposed over substantially an entire surface of the substrate 110. The buffer layer 120 can be formed of an inorganic material such as silicon oxide (SiO₂) or silicon nitride (SiNx) and can have a single-layer structure or a multi-layer structure.

A semiconductor layer 122 can be patterned and placed over the buffer layer 120. The semiconductor layer 122 can overlap the light-shielding layer 112. The semiconductor layer 122 can be formed of an oxide semiconductor material. In this situation, the light-shielding layer 112 can block light incident on the semiconductor layer 122, thereby preventing the semiconductor layer 122 from being degraded due to the light.

Alternatively, the semiconductor layer 122 can be formed of polycrystalline silicon. In this situation, both ends of the semiconductor layer 122 can be doped with impurities.

A gate insulation layer 124 and a gate electrode 126 can be sequentially placed over the semiconductor layer 122. The gate insulation layer 124 and the gate electrode 126 can be disposed to correspond to a central portion of the semiconductor layer 122. The gate insulation layer 124 can be patterned to have substantially the same shape as the gate electrode 126. Alternatively, the gate insulation layer 124 can be disposed over substantially the entire surface of the substrate 110.

The gate insulation layer 124 can be formed of an inorganic insulating material such as silicon oxide (SiO₂) or silicon nitride (SiNx). Here, when the semiconductor layer 122 is formed of an oxide semiconductor material, the gate insulation layer 124 can be formed of silicon oxide (SiO₂). Alternatively, when the semiconductor layer 122 is formed of polycrystalline silicon, the gate insulation layer 124 can be formed of silicon oxide (SiO₂) or silicon nitride (SiNx).

The gate electrode 126 can be formed of a conductive material such as metal. For example, the gate electrode 126 can be formed of at least one of aluminum (Al), copper (Cu), molybdenum (Mo), titanium (Ti), chromium (Cr), nickel (Ni), tungsten (W), or an alloy thereof and can have a single-layer structure or a multi-layer structure. For example, the gate electrode 126 can have a double-layer structure including a lower layer of a molybdenum-titanium (MoTi) alloy and an upper layer of copper (Cu), and the upper layer can have a thicker thickness than the lower layer. However, the embodiments of the present disclosure are not limited thereto.

An interlayer insulation layer 130 of an insulating material can be disposed over the gate electrode 126 over substantially the entire surface of the substrate 110. The interlayer insulation layer 130 can be formed of an inorganic insulating material, such as silicon oxide (SiO₂) or silicon nitride (SiNx), or can be formed of an organic insulating material, such as photo acryl or benzocyclobutene.

The interlayer insulation layer 130 can have semiconductor contact holes exposing top surfaces of both ends of the semiconductor layer 122. The semiconductor contact holes can be disposed at both sides of the gate electrode 126 and can be spaced apart from the gate electrode 126.

Next, source and drain electrodes 132 and 134 of a conductive material such as metal can be placed over the interlayer insulation layer 130.

The source and drain electrodes 132 and 134 can be formed of at least one of aluminum (Al), copper (Cu), molybdenum (Mo), titanium (Ti), chromium (Cr), nickel (Ni), tungsten (W), or an alloy thereof and can have a single-layer structure or a multi-layer structure. For example, each of the source and drain electrodes 132 and 134 can have a double-layer structure including a lower layer of a molybdenum-titanium (MoTi) alloy and an upper layer of copper (Cu), and the upper layer can have a thicker thickness than the lower layer. Alternatively, the source and drain electrodes 132 and 134 can have a triple-layer structure. However, the embodiments of the present disclosure are not limited thereto.

The source and drain electrodes 132 and 134 can be spaced apart from each other with the gate electrode 126 interposed therebetween and can be in contact with the both ends of the semiconductor layer 122 through the semiconductor contact holes.

The semiconductor layer 122, the gate electrode 126, the source electrode 132, and the drain electrode 134 can constitute the thin film transistor Tr. Here, the thin film transistor Tr can have a coplanar structure in which the gate electrode 126 and the source and drain electrodes 132 and 134 are disposed at the same side with respect to the semiconductor layer 122, for example, the gate electrode 126 and the source and drain electrodes 132 and 134 can be disposed over the semiconductor layer 122.

Alternatively, the thin film transistor Tr can have an inverted staggered structure in which the gate electrode and the source and drain electrodes are disposed at different sides with respect to the semiconductor layer, for example, the gate electrode can be disposed under the semiconductor layer and the source and drain electrodes can be disposed over the semiconductor layer. In this case, the semiconductor layer can be formed of an oxide semiconductor material or amorphous silicon.

However, the embodiments of the present disclosure are not limited thereto. The stacked structure of the components of the thin film transistor Tr can be varied.

The thin film transistor Tr can be the driving transistor T2 of FIG. 1. Meanwhile, at least one thin film transistor having the same structure as the thin film transistor Tr, for example, the switching transistor T1 of FIG. 1 and the sensing transistor T3 of FIG. 1 can be further formed in the non-emission area NEA over the substrate 110. However, the embodiments of the present disclosure are not limited thereto. Alternatively, at least one thin film transistor having a different structure from the thin film transistor Tr can be further provided in the non-emission area NEA over the substrate 110.

A passivation layer 140 of an insulating material can be disposed over the source and drain electrodes 132 and 134 as well as the gate electrode 126 over substantially the entire surface of the substrate 110. The passivation layer 140 can be formed of an inorganic insulating material, such as silicon oxide (SiO₂) or silicon nitride (SiNx).

A color filter 145 can be placed over the passivation layer 140. The color filter 145 can be placed to correspond to the emission area EA and can be one of red, green, and blue color filters, but other examples are possible. The color filter 145 can be placed at another location, e.g., below or above an encapsulation layer 170.

An overcoat layer 150 of an insulating material can be disposed over the color filter 145 over substantially the entire surface of the substrate 110. The overcoat layer 150 and the passivation layer 140 can have a source contact hole 152 exposing the source electrode 132.

The overcoat layer 150 can be formed of an organic insulating material. For example, the overcoat layer 150 can be formed of photo acryl. However, the embodiments of the present disclosure are not limited thereto.

The overcoat layer 150 can include a plurality of micro lenses 154 at a top surface thereof in the emission area EA. The plurality of micro lenses 154 can constitute a micro lens array (MLA), and each of the plurality of micro lenses 154 can have a depressed portion. Here, adjacent portions of two micro lenses 154 can form an embossed portion, and each depressed portion can be surrounded by the embossed portion. Accordingly, the micro lens array can be configured such that the depressed portion and the embossed portion can be alternately disposed or the micro lenses 154 can have other shapes and configurations.

Meanwhile, the overcoat layer 150 can have substantially a flat top surface in the non-emission area NEA. For instance, the micro lenses 154 can be formed only in the emission area EA and not necessarily in the non-emission area NEA.

A first electrode 162 of a conductive material having a relatively high work function can be placed over the overcoat layer 150 in the emission area EA. For example, the first electrode 162 can be formed of a transparent conductive material, such as indium tin oxide (ITO) or indium zinc oxide (IZO), but embodiments are not limited thereto.

The first electrode 162 can be extended into the non-emission area NEA and can be in contact with the source electrode 132 through the source contact hole 152.

In the emission area EA, the first electrode 162 can be formed along the morphology or contour of the top surface of the overcoat layer 150 including the micro lenses 154. Accordingly, the first electrode 162 can have an uneven top surface.

A bank 160 of an insulating material can be placed over the first electrode 162. The bank 160 can be formed of an organic insulating material. The bank 160 can overlap and cover edges of the first electrode 162. The bank 160 can have an opening 160a corresponding to the emission area EA, and a central portion of the first electrode 162 can be exposed through the opening 160a.

Next, a light-emitting layer 164 can be placed over the first electrode 162 exposed through the opening 160a of the bank 160. The light-emitting layer 164 can be disposed over substantially the entire surface of the substrate 110. Accordingly, in the emission area EA, the light-emitting layer 164 can be disposed over the first electrode 162 and in contact with the first electrode 162. In the non-emission area NEA, the light-emitting layer 164 can be disposed over the bank 160 and in contact with a top surface of the bank 160. Further, the light-emitting layer 164 can be in contact with a side surface of the bank 160.

The light-emitting layer 164 can emit white light and can include one or more of at least one hole auxiliary layer, at least one light-emitting material layer, and at least one electron auxiliary layer, which can constitute one light-emitting unit. The hole auxiliary layer can include at least one of a hole injection layer (HIL) and a hole transport layer (HTL). In addition, the electron auxiliary layer can include at least one of an electron injection layer (EIL) and an electron transport layer (ETL).

The light-emitting layer 164 can have a stack structure in which two or more light-emitting units emitting different colors are stacked, and a charge generation layer can be provided between two or more light-emitting units.

In the emission area EA, the light-emitting layer 164 can be formed along the morphology or contour of the top surface of the first electrode 162. Accordingly, in the emission area EA, the light-emitting layer 164 can be formed substantially along the morphology or contour of the top surface of the overcoat layer 150, and the light-emitting layer 164 can have an uneven top surface.

A second electrode 166 of a conductive material, having a relatively low work function, can be placed over the light-emitting layer 164 over substantially the entire surface of the substrate 110. In the emission area EA, the second electrode 166 can be disposed over the first electrode 162 and the light-emitting layer 164, and in the non-emission area NEA, the second electrode 166 can be disposed over the bank 160 and the light-emitting layer 164.

The second electrode 166 can be formed of aluminum, magnesium, silver, or an alloy thereof.

In the emission area EA, the second electrode 166 can be formed along the morphology or contour of the top surface of the light-emitting layer 164. Accordingly, in the emission area EA, the second electrode 166 can be formed substantially along the morphology or contour of the top surface of the overcoat layer 150 including the micro lenses 154, and the second electrode 166 can have an uneven top surface.

Here, the light-emitting layer 164 can have different thicknesses depending on the position. For example, a thickness of a portion of the light-emitting layer 164 corresponding to the depressed portion of the micro lens 154 can be thicker than a thickness of a portion of the light-emitting layer 164 corresponding to the embossed portion where two micro lenses 154 are adjacent to each other, and the light-emitting layer 164 can have the thinnest thickness between the depressed portion and the embossed portion.

The first electrode 162, the light-emitting layer 164, and the second electrode 166 can constitute the light-emitting diode De. Here, the first electrode 162 can function as an anode, and the second electrode 166 can function as a cathode, but the embodiments are not limited thereto.

The first electrode 162 can be formed of a transparent conductive material transmitting light, and the second electrode 166 can be formed of a metal material reflecting light. Accordingly, light from the light-emitting layer 164 can be emitted through the first electrode 162 and can pass through the color filter 145 and the substrate 110 to be output to the outside.

An encapsulation layer 170 can be placed over the second electrode 166 over substantially the entire surface of the substrate 110. The encapsulation layer 170 can be in the form of a face seal made of an organic or inorganic insulating material that is transparent and has adhesive properties or can have a multi-layer structure in which an inorganic layer, an organic layer, and an inorganic layer are stacked.

A counter substrate 180 can be placed over the encapsulation layer 170. The counter substrate 180 can be a glass substrate or a metal substrate. Alternatively, the counter substrate 180 can be formed in the form of a film. The counter substrate 180 and the substrate 110 can be referred to as first and second substrates or vice versa.

The encapsulation layer 170 and the counter substrate 180 can prevent substances such as moisture, dust or oxygen from being introduced into the light-emitting diode De from the outside or prevent an external impact from being applied to the light-emitting diode De.

As described above, the overcoat layer 150 can have the plurality of micro lenses 154 at the top surface thereof in the emission area EA, and the first electrode 162, the light-emitting layer 164, and the second electrode 166 placed over the overcoat layer 150 can be formed substantially along the morphology or contour of the top surface of the overcoat layer 150. Accordingly, in the emission area EA, the first electrode 162, the light-emitting layer 164, and the second electrode 166 can have uneven patterns corresponding to the micro lenses 154 of the overcoat layer 150. Further, in the emission area EA, the first electrode 162, the light-emitting layer 164, and the second electrode 166 can also have micro lenses.

The micro lenses 154 can improve the light extraction efficiency by changing the progress path of light so that the light, which was completely reflected and extinguished after being emitted from the light-emitting layer, can be extracted to the outside.

Meanwhile, the micro lenses 154 have a very small size in micro units, and the size and shape of the micro lenses 154 can directly affect the luminance of the organic light-emitting diode display device. Thus, managing the size and shape of the micro lenses 154 well is needed to enhance luminance characteristics of the organic light-emitting diode display device.

Accordingly, the organic light-emitting diode display device according to the embodiments of the present disclosure can include a lens pattern capable of monitoring the micro lens such as the formation of the micro lens.

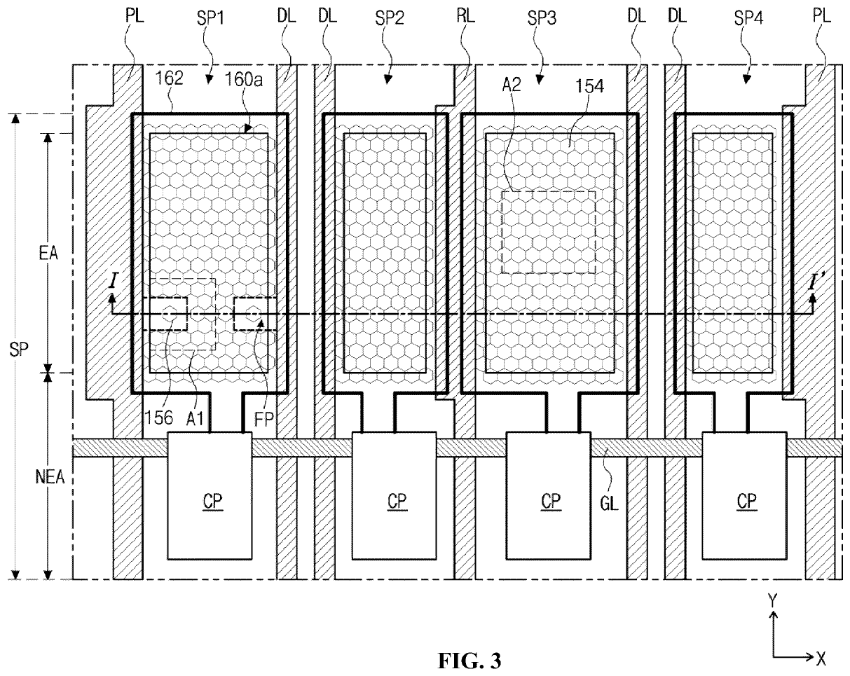

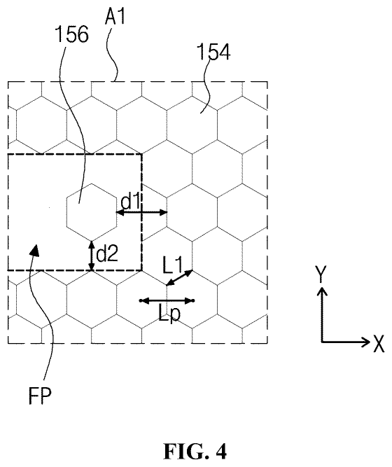

FIG. 3 is a schematic plan view of an organic light-emitting diode display device according to a first embodiment of the present disclosure, showing one pixel as an example. FIG. 4 is an enlarged plan view of an A1 area of FIG. 3. In this regard, FIG. 3 and FIG. 4 will now be described with reference to FIG. 1 and FIG. 2 together.

As shown in FIG. 3 and FIG. 4, in the organic light-emitting diode display device according to the first embodiment of the present disclosure, a gate line GL can extend along a first direction (e.g., X direction), and data lines DL, power lines PL, and a reference line RL can extend along a second direction (e.g., Y direction). The gate line GL can cross the data line DL, the power line PL, and the reference line RL to thereby define a plurality of sub-pixels SP. Here, the power line PL can be the high potential line for supplying the high potential voltage EVDD of FIG. 1, but other variations are possible.

Here, one reference line RL can be disposed between two power lines PL, two data lines DL can be disposed between one power line PL and one reference line RL, and each sub-pixel SP can be disposed substantially between one power line PL and one adjacent data line DL or between one reference line RL and one adjacent data line DL.

Each sub-pixel SP can have substantially a rectangular shape. However, the embodiments of the present disclosure are not limited thereto, and the shape of each sub-pixel SP can be changed. For instance, the shape can be a rhombus, a square or other shape.

As described above, each pixel can include a plurality of such sub-pixels SP. For example, each pixel can include four sub-pixels SP, for example, first, second, third, and fourth sub-pixels SP1, SP2, SP3, and SP4. The first, second, third, and fourth sub-pixels SP1, SP2, SP3, and SP4 can be sequentially arranged along the first direction. Here, the first sub-pixel SP1 can be a red sub-pixel, the second sub-pixel SP2 can be a blue sub-pixel, the third sub-pixel SP3 can be a white sub-pixel, and the fourth sub-pixel SP4 can be a green sub-pixel. However, the embodiments of the present disclosure are not limited thereto. Alternatively, the number of sub-pixels included in one pixel or the arrangement order of the red, green, blue sub-pixels with or without the white sub-pixel can be changed.

The areas or sizes of the first, second, third, and fourth sub-pixels SP1, SP2, SP3, and SP4 can be different from each other. For example, the areas of the first and third sub-pixels SP1 and SP3 can be larger than the areas of the second and fourth sub-pixels SP2 and SP4. In addition, the area of the third sub-pixel SP3 can be equal to or larger than the area of the first sub-pixel SP1, and the area of the second sub-pixel SP2 can be equal to or larger than the area of the fourth sub-pixel SP4. However, the embodiments of the present disclosure are not limited thereto. Alternatively, all areas or sizes of the first, second, third, and fourth sub-pixels SP1, SP2, SP3, and SP4 can be the same or substantially the same.

Here, one power line PL, two data lines DL, or one reference line RL can be disposed substantially between adjacent two sub-pixels among the sub-pixels SP1, SP2, SP3, and SP4. For example, two data lines DL can be disposed between the first and second sub-pixels SP1 and SP2 and between the third and fourth sub-pixels SP3 and SP4, one reference line RL can be disposed between the second and third sub-pixels SP2 and SP3, and one power line PL can be disposed between the first sub-pixel SP1 and a fourth sub-pixel SP4 of a previous pixel and between the fourth sub-pixel SP4 and a first sub-pixel SP1 of a next pixel. However, the embodiments of the present disclosure are not limited thereto.

Each sub-pixel SP can include the emission area EA and the non-emission area NEA. The light-emitting diode De (like in FIG. 1) can be provided in the emission area EA, and a circuit portion CP can be provided in the non-emission area NEA. The light-emitting diode De can include the first electrode 162 which is an anode, and the circuit portion CP can include the first, second, and third transistors T1, T2, and T3 and the storage capacitor Cst as shown in, e.g., FIG. 1.

In each of the first to fourth sub-pixels SP1, SP2, SP3, and SP4, the first electrode 162 can extend into the non-emission area NEA and can be electrically connected to the circuit portion CP. More particularly, the first electrode 162 can be electrically connected to the second transistor T2 of the circuit portion CP.

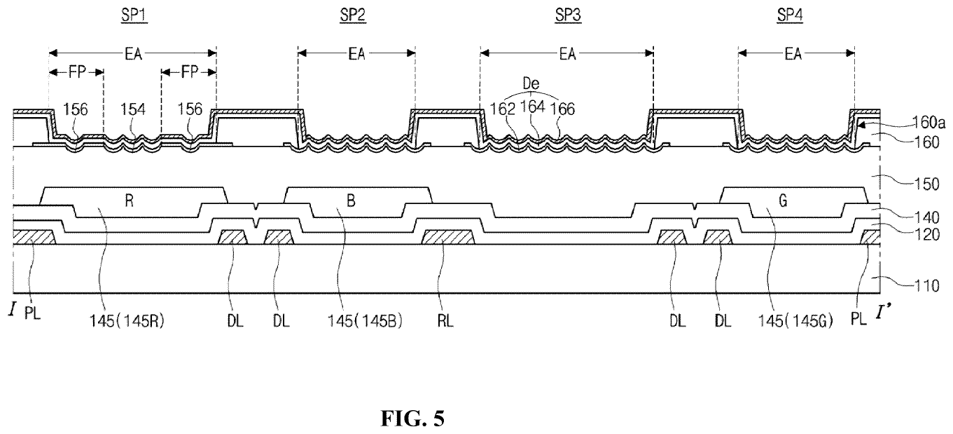

The emission area EA can be defined by the opening 160a of the bank (e.g., 160 in FIG. 5) exposing the first electrode 162. The opening 160a of the bank can have a smaller area than the first electrode 162 and can be disposed within the edges of the first electrode 162.

Here, each of the power lines PL, the data lines DL, and the reference line RL can overlap (e.g., overlap with) the first electrode 162 corresponding thereto and can be spaced apart from the opening 160a of the bank corresponding thereto. In this case, each of the power lines PL and the reference line RL can include a portion overlapping the first electrode 162, which has a wider width than other portions of the corresponding power line PL or reference line RL. However, the embodiments of the present disclosure are not limited thereto.

A plurality of micro lenses 154 can be provided in the emission area EA of each sub-pixel SP. The micro lenses 154 can be placed inside the opening 160a of the bank but also outside the opening 160a and can overlap the bank. Meanwhile, the micro lenses 154 can overlap the first electrode 162 and can be spaced apart from the edges of the first electrode 162 without overlapping.

The micro lenses 154 can have a hexagonal shape in plan and can form a honeycomb structure. Alternatively, the micro lenses 154 can have a circular shape, an oval shape, a rectangular shape, or the like.

Meanwhile, in the organic light-emitting diode display device according to the first embodiment of the present disclosure, at least one sub-pixel SP can include at least one flat portion FP in the emission area EA. For instance, in each pixel, there can be at least one sub-pixel SP each with at least one flat portion FP. At least one lens pattern 156 can be provided in the at least one flat portion FP, and the lens pattern 156 can be spaced apart from the micro lenses 154. For instance, each flat portion FP in the display device can have one lens pattern 156 alone, or some flat portions FP in the display device can be the lens patterns 156 while some other flat portion portions FP in the same display device do not. Other variations are possible. Further, the lens pattern 156 can have the same size and shape (or substantially the same size and shape) as the micro lens 54. For example, the lens pattern 156 can have a hexagonal shape in plan.

More particularly, in this example, the first sub-pixel SP1 can have two flat portions FP in the emission area EA while the second to fourth sub-pixels SP2, SP3 and SP4 do not have any such flat portion FP. In a variation, among the first to fourth sub-pixels SP1 to SP4, one or more sub-pixels can have such flat portions FP. The two flat portions FP can be placed at both sides of the emission area EA facing each other along the first direction, respectively, and can be disposed on the same straight line. Here, the phrase ‘on a straight line’ is interchangeably used with ‘in a straight line’. For instance, the two flat portions FP in the emission area EA can be aligned with each other.

One lens pattern 156 can be disposed in each of the two flat portions FP. Alternatively, the lens pattern 156 can be provided in only one of the two flat portions FP.

Meanwhile, the lens patterns 156 of adjacent pixels can be disposed on the same straight line. Specifically, the lens pattern 156, which is provided in the flat portion FP of the first sub-pixel SP1 of the pixel of FIG. 3, can be disposed to coincide with a lens pattern, which is provided in a flat portion of a first sub-pixel of a pixel adjacent thereto along the first direction, on a virtual horizontal line. For instance, all the flat portions FP in the display device along one row or column can be disposed on a same straight line or can be aligned with ach other.

Referring to FIG. 4, the lens pattern 156 can be spaced apart from the micro lens 154 adjacent thereto by a first distance d1 along the first direction (e.g., X direction) or by a second distance d2 along the second direction (e.g., Y direction). In addition, the lens pattern 156 can be spaced apart from a boundary of the opening 160a.

Specifically, the lens pattern 156 and the micro lens 154 adjacent to each other in the first direction can be spaced apart by the first distance d1, and the lens pattern 156 and the micro lens 154 adjacent to each other in the second direction can be spaced apart by the second distance d2. Here, the first distance d1 can be equal to or greater than a pitch Lp of the micro lens 154, and the second distance d2 can be equal to or greater than a side length LI of the micro lens 154. The pitch Lp of the micro lens 154 can be defined as a distance between centers of the adjacent micro lenses 154. Here, the micro lens 154 and the lens pattern 156 both have hexagon shapes, but other shapes and configurations are possible.

According to the embodiments of the present disclosure, the two flat portions FP can be used advantageously for measuring the size of the opening 160a of the bank.

The size of the emission area EA and the number of micro lenses 154 can be determined according to the size of the opening 160a of the bank. When the size of the opening 160a is smaller than a set range, the number of micro lenses 154 contributing to the light extraction can be reduced, thereby decreasing or affecting the light extraction efficiency. Accordingly, the embodiments of the present disclosure manage the size of the opening 160 within a specific range as follows.

In this example, the size of the opening 160a of FIG. 3 can be measured by photographing an optical image of the patterned bank (e.g., 160 in FIG. 5), but the optical image can be distorted due to the micro lenses 154. Accordingly, in the first embodiment of the present disclosure, the flat portions FP where the micro lenses 154 are not substantially placed can be provided in the emission area EA, and the boundary of the opening 160a can be disposed over the flat portions FP, so that the size of the opening 160a of the bank and the distance between the openings 160, for example, the width of the bank, can be accurately measured without distortion of the gray level.

In an example, each flat portion FP can be greater than or equal to the total area of four micro lenses 154 in size while be smaller than or equal to the total area of nine micro lenses 154 in size, but the embodiments of the present disclosure are not limited thereto.

Meanwhile, the lens pattern 156 in each flat portion FP can be used for monitoring the micro lenses 154, and this will be described in detail later.

The cross-sectional structure of the organic light-emitting diode display device according to the first embodiment of the present disclosure will be described with reference to FIG. 5.

FIG. 5 is a cross-sectional view corresponding to line I-I′ of FIG. 3.

In FIG. 5, the substrate 110 can include the plurality of sub-pixels, for example, the first, second, third, and fourth sub-pixels SP1, SP2, SP3, and SP4. The power lines PL, the data lines DL, and the reference line RL can be placed over the substrate 110.

The buffer layer 120 and the passivation layer 140 can be sequentially placed over the power lines PL, the data lines DL, and the reference line RL. The gate line GL of FIG. 3 can be placed between the buffer layer 120 and the passivation layer 140.

Next, the color filter 145 can be placed over the passivation layer 140. The color filter 145 can include red, green, and blue color filters 145R, 145G, and 145B. The red color filter 145R can be disposed in the first sub-pixel SP1, the blue color filter 145B can be disposed in the second sub-pixel SP2, and the green color filter 145G can be disposed in the fourth sub-pixel SP4. No color filter can be disposed in the third sub-pixel SP3 which can be a white sub-pixel.

The color filter 145 can overlap the lines adjacent thereto. For instance, the red color filter 145R can overlap one power line PL and adjacent one data line DL, the blue color filter 145B can overlap another data line DL and the reference line RL, and the green color filter 145G can overlap another data line DL and another power line PL.

Although FIG. 5 shows that the red, blue, and green color filters 145R, 145B, and 145G are spaced apart from each other, the embodiments of the present disclosure are not limited thereto. Alternatively, adjacent ones of the red, blue, and green color filters 145R, 145B, and 145G can overlap each other. For example, adjacent red and blue color filters 145R and 145B can overlap each other, and adjacent green and red color filters 145G and 145R can overlap each other.

The overcoat layer 150 can be placed over the color filter 145. The overcoat layer 150 can have the plurality of micro lenses 154 at the top surface thereof in the emission area EA of each sub-pixel SP1, SP2, SP3, and SP4.

In the first, second, and fourth sub-pixels SP1, SP2, and SP4, the micro lenses 154 can overlap the color filter 145. Each micro lens 154 can include the depressed portion, and adjacent portions of two or more micro lenses 154 can form the embossed portion.

Meanwhile, the emission area EA of the first sub-pixel SP1 can include at least one flat portion FP. The top surface of the overcoat layer 150 can be partially flat or partially substantially flat (e.g., not curved, not depressed, or not embossed, etc.) to correspond to the flat portion FP, and at least one lens pattern 156 can be provided in the flat portion FP. The lens pattern 156 can have the same size and shape (or substantially the same size and shape) as one micro lens 154. For example, the lens pattern 156 can include one depressed portion.

As an example, the emission area EA of the first sub-pixel SP1 can include two flat portions FP (e.g., as shown in FIG. 3), and the flat portions FP can be disposed at both sides or opposing sides of the emission area EA facing each other. One lens pattern 156 can be placed in each of the flat portions FP. The top surface of the overcoat layer 150 corresponding to the flat portions FP except for the lens pattern 156 can be flat or substantially flat. Accordingly, the overcoat layer 150 can have the flat top surface between the lens pattern 156 and the micro lens 154.

Next, the first electrode 162 of the light-emitting diode De can be placed over the overcoat layer 150 in each of the first, second, third, and fourth sub-pixels SP1, SP2, SP3, and SP4. The first electrode 162 can overlap and cover the micro lenses 154. In addition, the first electrode 162 can overlap and cover the lens pattern 156 of the flat portion FP.

The bank 160 can be provided over the first electrode 162. The bank 160 can have the opening 160a corresponding to the emission area EA of each sub-pixel SP1, SP2, SP3, and SP4. The first electrode 162 can be exposed through each opening 160a.

The bank 160 can overlap the micro lenses 154 in each of the first, second, third, and fourth sub-pixels SP1, SP2, SP3, and SP4. Here, the bank 160 can overlap a portion of each micro lens 154. In the first sub-pixel SP1, the bank 160 can overlap the micro lenses 154 in an outer area except for the flat portions FP.

Meanwhile, in the first sub-pixel SP1, two side surfaces of the bank 160 facing each other can be disposed over the two flat portions FP, respectively. For instance, the opening 160a (which can be defined by the two opposite side surfaces of the bank 160) can be disposed over the two flat portions FP. Further, the two side surfaces of the bank 160 facing each other can be spaced apart from the micro lenses 154 without overlapping.

The light-emitting layer 164 of the light-emitting diode De can be placed over the first electrode 162 and the bank 160. The light-emitting layer 164 can be disposed over substantially the entire surface of the substrate 110. For instance, the light-emitting layer 164 can extend to cover all the first electrodes 162 and the bank 160 of all the sub-pixels of the display device. The light-emitting layer 164 can emit white light and can have a stack structure, which includes light-emitting units emitting different colors.

The second electrode 166 can be placed over the light-emitting layer 164. The second electrode 166 can be disposed over substantially the entire surface of the substrate 110. For instance, the second electrode 166 can extend to cover all the light-emitting layer 164 and the bank 160 of all the sub-pixels of the display device.

The first electrode 162, the second electrode 166, and the light-emitting layer 164 interposed therebetween can constitute the light-emitting diode De. Each sub-pixel includes one such light-emitting diode De.

As described above, the overcoat layer 150 can have the micro lenses 154 at its top surface in the emission area EA. The first electrode 162, the light-emitting layer 164, and the second electrode 166 disposed over the overcoat layer 150 can be formed along the morphology or contour of the top surface of the overcoat layer 150. Accordingly, the first electrode 162, the light-emitting layer 164, and the second electrode 166 can also have the micro lens shape at the respective top surfaces in the emission area EA, and the micro lenses 154 can change the progress path of light, thereby improving the light extraction efficiency.

In addition, the top surface of the overcoat layer 150 can have the flat portions FP in some emission areas EA, and the side surfaces of the bank 160 can be disposed over the flat portions FP to non-overlap and/or to be spaced apart from the micro lenses 154, so that the size of the opening 160a and the width of the bank 160 can be accurately measured without distortion of the gray level. Therefore, since the opening 160a of the bank 160 can be managed with a specific range, it is possible to prevent the light extraction efficiency of the display device from being lowered.

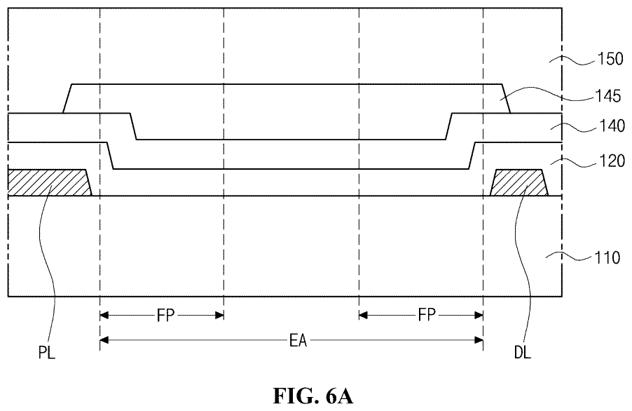

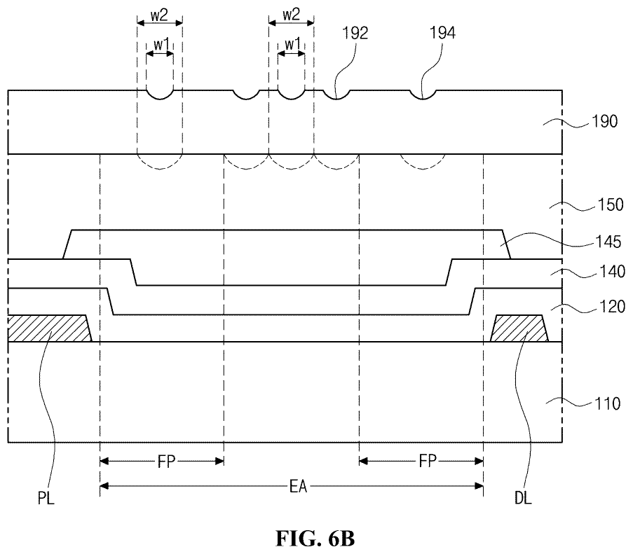

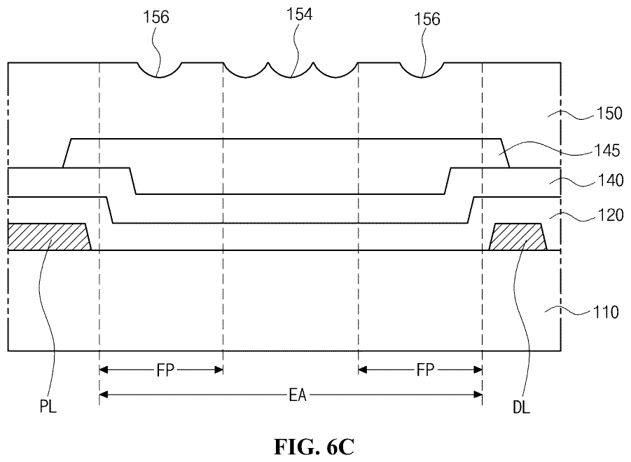

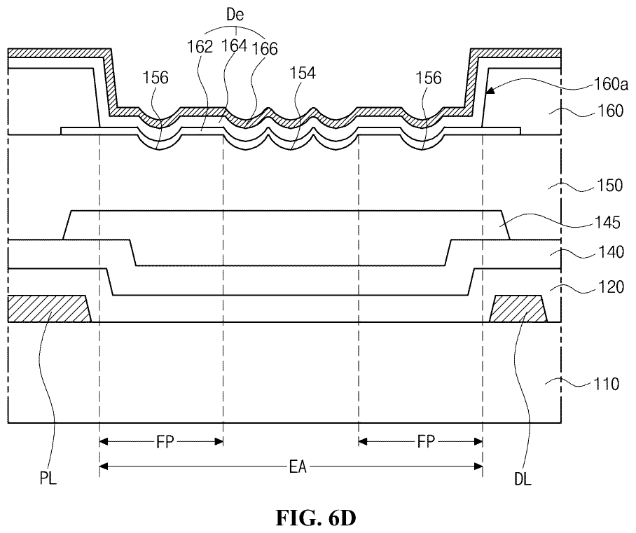

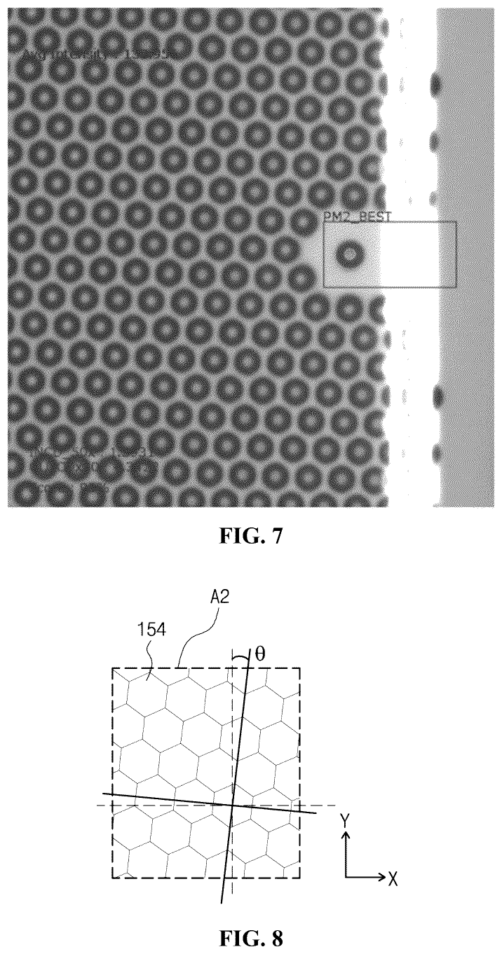

As described above, the lens pattern 156 of the overcoat layer 150 in each flat portion FP can be used for monitoring the micro lenses 154. This will be described with reference to FIGS. 6A to 6D and FIG. 7.

FIGS. 6A to 6D are cross-sectional views of an organic light-emitting diode display device for explaining a method of manufacturing the same according to the first embodiment of the present disclosure and show a cross-section corresponding to the first sub-pixel. FIG. 7 is an optical image measured in the process of monitoring micro lenses according to an example of the present disclosure. Here, FIGS. 6A to 6D focus on showing a sub-pixel with the flat portions FP, such as the first sub-pixel SP1 of FIG. 5, for the sake of brevity. The other sub-pixels (e.g., without the flat portions FP) can be made similarly, but without the flat portions FP.

In FIG. 6A, the power line PL and the data line DL can be formed over the substrate 110 provided with the emission area EA having at least one flat portion FP. Further, the buffer layer 120 and the passivation layer 140 can be sequentially formed over the power line PL and the data line DL. Then, the color filter 145 can be formed over the passivation layer 140 in the emission area EA, and the overcoat layer 150 can be formed over the color filter 145.

In an example, the emission area EA can have two flat portions FP, and the flat portions FP can be disposed at both sides of the emission area EA and spaced apart from each other.

Next, in FIG. 6B, photoresist can be applied over the overcoat layer 150, and the photoresist can be exposed to light through a photolithography process using a photo mask and developed, thereby forming a photoresist layer 190 having a plurality of first patterns 192 and at least one second pattern 194. The first patterns 192 and the second pattern 194 can have a concave shape at the top surface of the photoresist layer 190 in the emission area EA.

Here, the photoresist can have a positive photosensitivity in which a portion exposed to light is removed after developing. However, the embodiments of the present disclosure are not limited thereto.

The plurality of first patterns 192 can be formed in the emission area EA excluding the flat portions FP, and one second pattern 194 can be formed in each flat portion FP.

The first patterns 192 can be disposed to correspond to the micro lenses (to be formed) indicated by a dotted line at the top surface of the overcoat layer 150. The second pattern 194 can be disposed to correspond to the lens pattern (to be formed) indicated by a dotted line at the top surface of the overcoat layer 150.

The size and shape of the first patterns 192 can directly affect the size and shape of the micro lenses. If the first patterns 192 are not properly formed, a defect in the micro lenses can occur, leading to a defect in a panel of a display device to be formed.

Accordingly, in the embodiments of the present disclosure, the size and shape of the first patterns 192 can be measured by providing the second pattern 194 having the same size and shape (or substantially the same size and shape) as the first patterns 192.

Therefore, the second pattern 194 in the photoresist layer 190 can have the same sizes as the first patterns 192 in the photoresist layer 190. For instance, each of the first and second patterns 192 and 194 can be the same in size and/or shape with each other. Each of the first and second patterns 192 and 194 can have a (same) first width w1. Here, the first width of the first and second patterns 192 and 194 can be smaller than a second width w2 of the micro lenses and the lens patterns (indicated by the dotted lines).

Then, the second pattern 194 can be measured. The measurement of the second pattern 194 can be performed using optical equipment. The uniformity according to dispersion can be measured by measuring the size and shape of the second pattern 194 for each location in the entire display area.

A distance between the first pattern 192 and the second pattern 194 adjacent to each other can be greater than a distance between adjacent first patterns 192, and a top surface of the photoresist layer 190 between the first pattern 192 and the second pattern 194 can be substantially flat.

Accordingly, as shown in an example of FIG. 7, since a relatively large flat surface can be provided around the second pattern 194 disposed in the flat portion FP, light and shade can be distinguished, and it is possible to accurately measure the size and shape of the second pattern 194.

If the measured size and shape of the second pattern 194 are determined to be within the set range or are determined to be uniformly formed over the entire display area of the display device, an ashing process can be carried out.

On the other hand, if the measured size and shape of the second pattern 194 are determined to be not within the set range or are determined to be not uniformly formed over the entire display area, the photoresist layer 190 can be removed through a stripping process since stains can occur and efficiency can be reduced if another process such as an ashing process is used.

In such a case, photoresist can be applied and a photoresist layer 190 having new first and second patterns 192 and 194 can be sequentially formed using a photolithography process through rework. Then, the size and shape of the second pattern 194 can be measured again.

Next, when the measured size and shape of the second pattern 194 are determined to be within the set range, as shown in FIG. 6C, by performing an ashing process as discussed above, the photoresist layer 190 can be removed, and the plurality of micro lenses 154 and the lens pattern 156 can be formed at the top surface of the overcoat layer 150.

The plurality of micro lenses 154 can be provided in the emission area EA except for the flat portion FP, and the lens pattern 156 can be provided in the flat portion FP and can be spaced apart from the micro lenses 154. The top surface of the overcoat layer 150 can be flat between the lens pattern 156 and the micro lens 154 adjacent to each other. The lens pattern 156 can have the same size and shape (or substantially the same size and shape) as the micro lens 154.

Next, as shown in FIG. 6D, the light-emitting diode De and the bank 160 can be formed over the overcoat layer 150 including the micro lenses 154 and the lens pattern 156. Specifically, the first electrode 162 can be formed over the overcoat layer 150 in the emission area EA, the bank 160 with the opening 160a exposing the first electrode 162 can be formed over the first electrode 162, and the light-emitting layer 164 and the second electrode 166 can be sequentially formed over the exposed first electrode 162 and the bank 160.

In the emission area EA including the flat portions FP, the overcoat layer 150 can have the micro lenses 154 and the lens pattern 156, whereas the first electrode 162, the light-emitting layer 164, and the second electrode 166 can be formed along the morphology or contour of the top surface of the overcoat layer 150. Accordingly, the first electrode 162, the light-emitting layer 164, and the second electrode 166 can also have the micro lens shape and the lens pattern shape in the emission area EA.

As such, in the organic light-emitting diode display device according to the first embodiment of the present disclosure, by placing the lens pattern 156 having the same size and shape as (or substantially the same size and shape) the micro lenses 154 in the flat portions FP provided in the emission area, the size of the opening 160a of the bank 160 can be accurately measured and managed, and at the same time, the manufacturing of the micro lenses 154 can be more efficiently managed and controlled.

Since rework is possible through the monitoring, obtaining pattern consistency of the micro lenses 154 can be achieved and improved. Accordingly, the light extraction efficiency can be improved, and the power consumption can be reduced to implement the low power consumption for the display device.

In addition, since the yield of the display device can be improved by the rework and process management through the monitoring, the production energy can be reduced, and the process optimization can be implemented. Furthermore, production hazards and regulated substances can be reduced, and thus it can be helpful for recycling.

Meanwhile, since the lens pattern 156 can be placed as close to the micro lenses 154 in the opening 160a as possible, the monitoring effect can be maximized.

Further, since the lens pattern 156 is disposed in the opening 160a, the lens pattern 156 can change the progress path of light so as to extract the light to the outside like the micro lenses 154, thereby further improving the light extraction effect.

Meanwhile, in a second embodiment of the present disclosure, the micro lenses in at least one sub-pixel can be provided to be rotated. Such second embodiment of the present disclosure will be described with reference to FIG. 8. The second embodiment is substantially the same as the first embodiment, but the micro lenses in at least one sub-pixel can be rotated.

Particularly, FIG. 8 is a schematic plan view of an organic light-emitting diode display device according to the second embodiment of the present disclosure and is an enlarged view corresponding to an area A2 of FIG. 3 according to the second embodiment. The first to fourth sub-pixels can be sequentially provided over the substrate 110.

In FIG. 8, the micro lenses 154 provided in at least one sub-pixel can be disposed as rotated clockwise or counterclockwise with respect to the first and second directions. In this example, the first direction is the X direction, and the second direction is the Y direction, but other examples are possible.

For example, the micro lenses 154 in the sub-pixel can be disposed as rotated clockwise with an angle θ with respect to the first and second directions. Accordingly, the line connecting the centers of the micro lenses 154 adjacent to each other can have the angle θ with respect to the first and/or second direction. The micro lenses 154 having the hexagonal shapes as disposed show the rotation at the angle θ (e.g., off-centered), in comparison to the first embodiment as shown in FIGS. 3 and 4.

Here, the angle θ can be an acute or slanted angle. For instance, the angle θ can be selected from a range greater than or equal to 0 degrees and less than 60 degrees. For instance, the rotated angle of the micro lenses 154 can be between 0 to 60 degrees rotated in the clockwise or counterclockwise direction.

Further, the micro lenses 154 of all or some sub-pixels of the display device can be rotated as shown in FIG. 8. In this case, the micro lenses 154 of the adjacent sub-pixels can have different rotation angles.

For example, the micro lenses 154 in twenty sub-pixels arranged in a matrix form can be rotated clockwise or counterclockwise with a rotation angle of 3 degree difference and randomly arranged. However, the embodiments of the present disclosure are not limited thereto.

As such, in the organic light-emitting diode display device according to the second embodiment of the present disclosure, the micro lenses 154 in at least one sub-pixel can be disposed as rotated at a specific angle with respect to the first and second directions. Accordingly, the diffraction pattern of the reflected light generated by the regular arrangement of the micro lenses 154 can be offset or minimized, or the diffraction pattern of the reflected light can be irregular or random, so the occurrence of a radial rainbow pattern or a radial circular ring pattern of the reflected light can be suppressed or minimized. Therefore, the image quality of the display device can be improved.

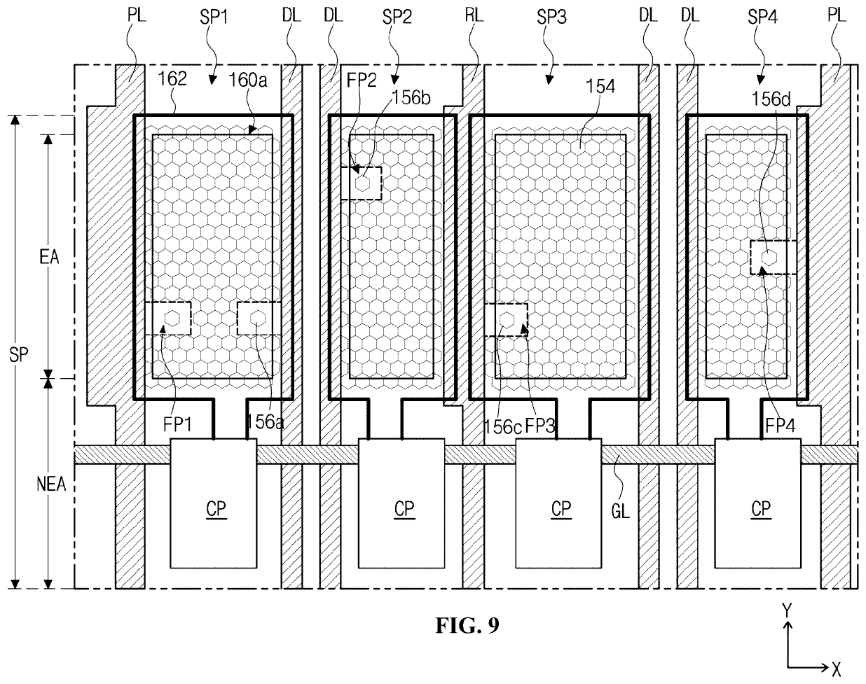

In a third embodiment of the present disclosure, the flat portion FP can be provided in all sub-pixels. An organic light-emitting diode display device according to such third embodiment of present disclosure will now be described with reference to FIG. 9.

Particularly, FIG. 9 is a schematic plan view of an organic light-emitting diode display device according to the third embodiment of the present disclosure. The organic light-emitting diode display device according to the third embodiment of the present disclosure has substantially the same configuration as that of the first embodiment or the second embodiment (e.g., similar to FIG. 3), but in the third embodiment, a flat portion is provided in each of all the sub-pixels of the display device. The same or similar parts as the first or second embodiment will be designated by the same or similar references, and explanation for the same parts will be omitted or shortened.

As shown in FIG. 9, in the organic light-emitting diode display device according to the third embodiment of the present disclosure, each of the first, second, third, and fourth sub-pixels SP1, SP2, SP3, and SP4 can have at least one flat portion FP (e.g., FP1, FP2, FP3, and FP4) in the emission area EA.

More particularly, the first sub-pixel SP1 can have two first flat portions FP1 in the emission area EA, and the second, third, and fourth sub-pixels SP2, SP3, and SP4 can have second, third, and fourth flat portions FP2, FP3, and FP4 in the emission area EA, respectively. For instance, each of the second, third, and fourth sub-pixels SP2, SP3, and SP4 can have only one flat portion in the emission area EA.

The arrangement of the first, second, third, and fourth flat portions FP1, FP2, FP3, and FP4 can be different in the first, second, third, and fourth sub-pixels SP1, SP2, SP3, and SP4. In this case, at least one of the first, second, third, and fourth flat portions FP1, FP2, FP3, and FP4 can be disposed on a different straight line from others.

For example, the first flat portions FP1 can be placed at both sides of the emission area EA of the first sub-pixel SP1 facing each other along the first direction (e.g., the X direction), respectively, and can be disposed on the same straight line along the first direction. The configuration of the two flat portions FP in the first sub-pixel SP1 in FIG. 9 can be the same as or similar to that of the two flat portions FP in the first sub-pixel SP1 in FIG. 3.

The second flat portion FP2 can be placed at one side of the emission area EA of the second sub-pixel SP2, (e.g., a left side of the emission area EA of the second sub-pixel SP2) and can be disposed on a different straight line from the first flat portions FP1 along the first direction.

The third flat portion FP3 can be placed at one side of the emission area EA of the third sub-pixel SP3, (e.g., a left side of the emission area EA of the third sub-pixel SP3) and can be disposed on substantially the same straight line as the first flat portions FP1 along the first direction.

The fourth flat portion FP4 can be placed at one side of the emission area EA of the fourth sub-pixel SP4, (e.g., a right side of the emission area EA of the fourth sub-pixel SP4) and can be disposed on the different straight line from the first, second, and third flat portions FP1, FP2, and FP3 along the first direction.

However, the embodiments of the present disclosure are not limited thereto, and the arrangement of the first, second, third, and fourth flat portions FP1, FP2, FP3, and FP4 can be changed. For instance, each of one or more of the second to fourth sub-pixels SP2 to SP4 can have two oppositely disposed flat portions FP similar to the first flat portions FP2. Further, the flat portions FP amongst the first to fourth sub-pixels SP1 to SP4 can be aligned with each other, or can be partially aligned with other (e.g., as shown in FIG. 9) where the first and third flat portions FP1 and FP3 are aligned with each other but are not aligned with the second or fourth flat portion FP2, FP4).

At least one lens pattern 156 (e.g., 156a, 156b, 156c, and 156d) can be provided in each of the first, second, third, and fourth flat portions FP1, FP2, FP3, and FP4. Specifically, the first lens pattern 156a can be provided in each first flat portion FP1, the second lens pattern 156b can be provided in the second flat portion FP2, the third lens pattern 156c can be provided in the third flat portion FP3, and the fourth lens pattern 156d can be provided in the fourth flat portion FP4.

The first, second, third, and fourth lens patterns 156a, 156b, 156c, and 156d can have the same size and shape (or substantially the same size and shape) as the micro lenses 154.

The first, second, third, and fourth lens patterns 156a, 156b, 156c, and 156d can be used for monitoring the micro lenses 154. The method of forming the first, second, third, and fourth lens patterns 156a, 156b, 156c, and 156d and the micro lenses 154 and the monitoring process can be the same as or substantially the same as those of FIGS. 6A to 6D and FIG. 7.

As such, since the organic light-emitting diode display device according to the third embodiment of the present disclosure can include at least one flat portion FP1, FP2, FP3, and FP4 in the emission area EA of each sub-pixel SP1, SP2, SP3, and SP4 and at least one lens pattern 156a, 156b, 156c, and 156d in each of the flat portions FP1, FP2, FP3, and FP4, the micro lenses 154 can be manufactured and managed more precisely for each sub-pixel SP1, SP2, SP3, and SP4, thereby providing the display device of a better quality.

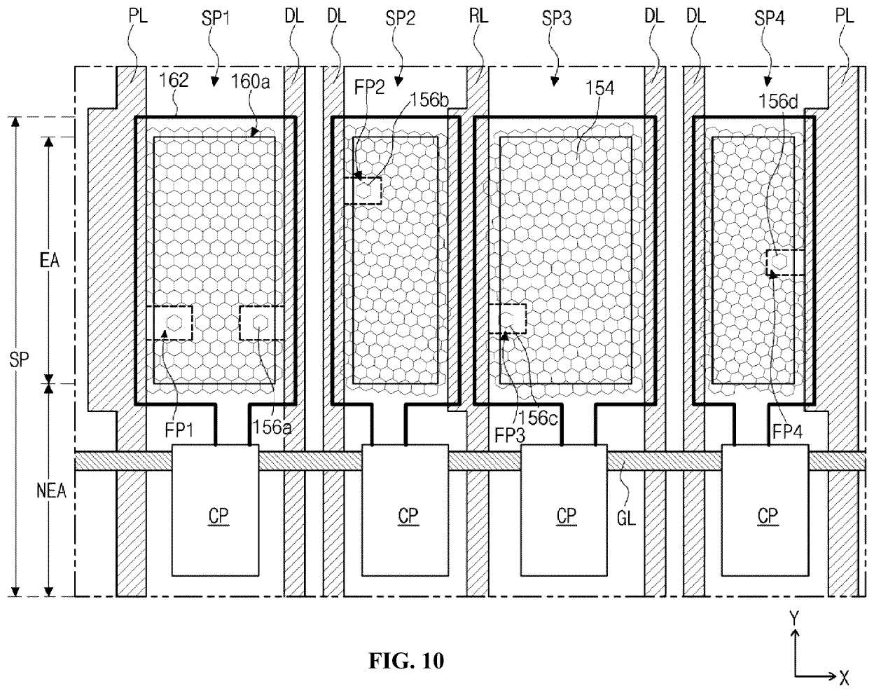

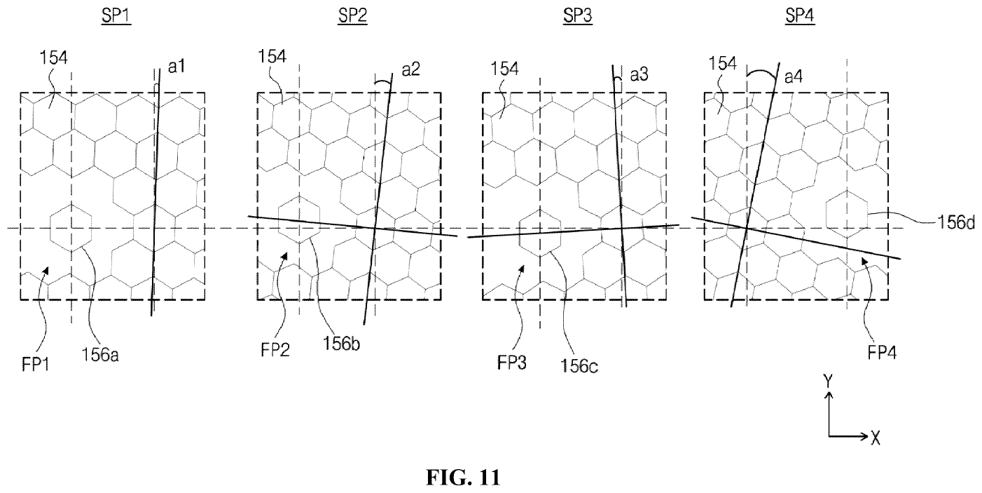

In a fourth embodiment of the present disclosure, the micro lenses of some sub-pixels can be provided as rotated, while the lens patterns of the sub-pixels can be provided as not rotated. Such fourth embodiment of the present disclosure will now be described with reference to FIG. 10 and FIG. 11.

Particularly, FIG. 10 is a schematic plan view of an organic light-emitting diode display device according to the fourth embodiment of the present disclosure. FIG. 11 is an enlarged plan view of emission areas of respective sub-pixels of FIG. 10 and shows the emission areas including flat portions. The views shown in FIG. 11 are merely samples and can be applied to the display area in its entirety or in part of the display device. The organic light-emitting diode display device according to the fourth embodiment of the present disclosure has substantially the same configuration as that of the first, second, or third embodiment, but the micro lenses of each (or some) of the sub-pixels as disposed are rotated. The same or similar parts as the first, second, or third embodiment will be designated by the same or similar references, and explanation for the same parts will be omitted or shortened.

In FIG. 10 and FIG. 11, the first, second, third, and fourth flat portions FP1, FP2, FP3, and FP4 can be provided in the emission areas EA of the first, second, third, and fourth sub-pixels SP1, SP2, SP3, and SP4, respectively. The plurality of micro lenses 154 can be provided in each emission area EA, and the first, second, third, and fourth lens patterns 156a, 156b, 156c, and 156d can be provided in the first, second, third, and fourth flat portions FP1, FP2, FP3, and FP4, respectively.

In the fourth embodiment, the micro lenses 154 of the respective sub-pixels SP1, SP2, SP3, and SP4 can be rotated differently from each other with respect to the first and second directions. Here, the first direction is the X direction, and the second direction is the Y direction.

In particular, the micro lenses 154 of the first sub-pixel SP1 can be rotated clockwise to a first angle a1 as shown in FIG. 11 and disposed in the rotated manner. Accordingly, in the first sub-pixel SP1, the line connecting the centers of the micro lenses 154 adjacent to each other can have the first angle a1 with respect to the first and/or second direction.

The micro lenses 154 of the second sub-pixel SP2 can be rotated clockwise to a second angle a2 as shown in FIG. 11 and disposed in the rotated manner. Accordingly, in the second sub-pixel SP2, the line connecting the centers of the micro lenses 154 adjacent to each other can have the second angle a2 with respect to the first and/or second direction.

The micro lenses 154 of the third sub-pixel SP3 can be rotated counterclockwise to a third angle a3 as shown in FIG. 11 and disposed in the rotated manner. Accordingly, in the third sub-pixel SP3, the line connecting the centers of the micro lenses 154 adjacent to each other can have the third angle a3 with respect to the first and/or second direction.

The micro lenses 154 of the fourth sub-pixel SP4 can be rotated clockwise to a fourth angle a4 as shown in FIG. 11 and disposed in the rotated manner. Accordingly, in the fourth sub-pixel SP4, the line connecting the centers of the micro lenses 154 adjacent to each other can have the fourth angle a4 with respect to the first and/or second direction.

The first, second, third, and fourth angles a1, a2, a3, and a4 each can be an acute or slanted angle. For instance, the first, second, third, and fourth angles a1, a2, a3, and a4 can each be selected from a range greater than or equal to 0 degrees and less than 60 degrees and can be different from each other. For example, at least one of the first, second, third, and fourth angles a1, a2, a3, and a4 can be different from at least another of the first, second, third, and fourth angles a1, a2, a3, and a4.

For example, the micro lenses 154 in twenty sub-pixels arranged in a matrix form can be disposed as rotated clockwise or counterclockwise with a rotation angle of 3 degree difference and randomly arranged. However, the embodiments of the present disclosure are not limited thereto.

Meanwhile, the first, second, third, and fourth lens patterns 156a, 156b, 156c, and 156d respectively provided in the first, second, third, and fourth flat portions FP1, FP2, FP3, and FP4 may not be rotated with respect to the first and second directions. For example, while the micro lenses 154 are disposed as rotated, the corresponding lens patterns 156 may not be rotated. In the example shown in FIG. 11, in the first sub-pixel SP1, the first lens pattern 156a is not rotated while the micro lenses 154 are rotated at the first angle a1. Similarly, in the second sub-pixel SP2, the second lens pattern 156b is not rotated while the micro lenses 154 are rotated at the second angle a2. In in the third sub-pixel SP3, the third lens pattern 156c is not rotated while the micro lenses 154 are rotated at the third angle a3. In the fourth sub-pixel SP4, the fourth lens pattern 156d is not rotated while the micro lenses 154 are rotated at the fourth angle a4.

Accordingly, in each of the first, second, third, and fourth sub-pixels SP1, SP2, SP3, and SP4, a distance between each of the first, second, third, and fourth lens patterns 156a, 156b, 156c, and 156d and the micro lens 154 adjacent thereto can vary depending on the direction.

As such, in the organic light-emitting diode display device according to the fourth embodiment of the present disclosure, the micro lenses 154 in the respective sub-pixels SP1, SP2, SP3, and SP4 can be disposed as rotated at different angles with respect to the first and/or second directions. Accordingly, the diffraction pattern of the reflected light generated by the regular arrangement of the micro lenses 154 can be offset or minimized, or the diffraction pattern of the reflected light can be irregular or random, so the occurrence of a radial rainbow pattern or a radial circular ring pattern of the reflected light can be suppressed or minimized. Therefore, the image quality of the display device can be improved.

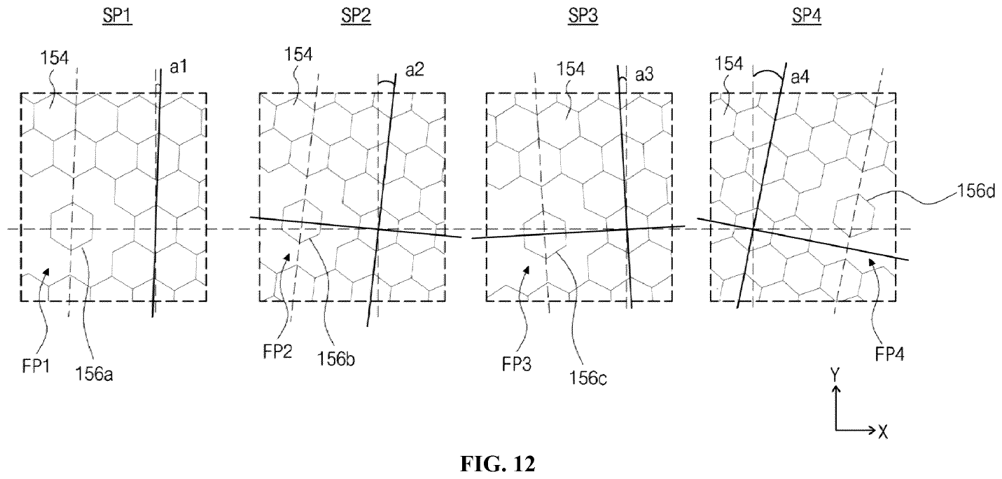

Meanwhile, the lens patterns 156a, 156b, 156c, and 156d can be rotated like the micro lenses 154. An organic light-emitting diode display device according to such a fifth embodiment of present disclosure will be described with reference to FIG. 12.

FIG. 12 is an enlarged schematic plan view of an organic light-emitting diode display device according to the fifth embodiment of the present disclosure and shows emission areas of each sub-pixel including flat portions. The organic light-emitting diode display device according to the fifth embodiment of the present disclosure has substantially the same configuration as that of the first, second, third, or fourth embodiment, but the lens pattern of each of the sub-pixels is rotated in the same manner as the corresponding micro lenses. The same or similar parts as the first, second, third, or fourth embodiment will be designated by the same or similar references, and explanation for the same parts will be omitted or shortened.

In FIG. 12, the first, second, third, and fourth flat portions FP1, FP2, FP3, and FP4 can be provided in the emission areas EA of the first, second, third, and fourth sub-pixels SP1, SP2, SP3, and SP4, respectively. The plurality of micro lenses 154 can be provided in each emission area EA, and the first, second, third, and fourth lens patterns 156a, 156b, 156c, and 156d can be provided in the first, second, third, and fourth flat portions FP1, FP2, FP3, and FP4, respectively.

The micro lenses 154 and the first, second, third, and fourth lens patterns 156a, 156b, 156c, and 156d of the respective sub-pixels SP1, SP2, SP3, and SP4 can be rotated differently from each other with respect to the first and second directions.

In particular, both the micro lenses 154 and the first lens pattern 156a of the first sub-pixel SP1 can be rotated clockwise to a first angle a1. Accordingly, in the first sub-pixel SP1, the line connecting the centers of the micro lenses 154 and the center of the first lens pattern 156a adjacent to each other can have the first angle a1 with respect to the first and/or second direction. For example, such lines can be parallel to each other.

In the same manner, both the micro lenses 154 and the second lens pattern 156b of the second sub-pixel SP2 can be rotated clockwise to a second angle a2. Accordingly, in the second sub-pixel SP2, the line connecting the centers of the micro lenses 154 and the second lens pattern 156b adjacent to each other can have the second angle a2 with respect to the first and/or second direction. For example, such lines can be parallel to each other.

Further, both the micro lenses 154 and the third lens pattern 156c of the third sub-pixel SP3 can be rotated counterclockwise to a third angle a3. Accordingly, in the third sub-pixel SP3, the line connecting the centers of the micro lenses 154 and the center of the third lens pattern 156c adjacent to each other can have the third angle a3 with respect to the first and/or second direction. For example, such lines can be parallel to each other.

Also both the micro lenses 154 and the fourth lens pattern 156d of the fourth sub-pixel SP4 can be rotated clockwise with a fourth angle a4. Accordingly, in the fourth sub-pixel SP4, the line connecting the centers of the micro lenses 154 and the center of the fourth lens pattern 156d adjacent to each other can have the fourth angle a4 with respect to the first and/or second direction. For example, such lines can be parallel to each other.

The first, second, third, and fourth angles a1, a2, a3, and a4 can be acute or slanted angles. For instance, the first, second, third, and fourth angles a1, a2, a3, and a4 each can be selected from a range greater than or equal to 0 degrees and less than 60 degrees and can have different values from each other.

As such, in the organic light-emitting diode display device according to the fifth embodiment of the present disclosure, the first, second, third, and fourth lens patterns 156a, 156b, 156c, and 156d can be rotated with or to the same angles as the micro lenses 154 of the respective sub-pixels SP1, SP2, SP3, and SP4, so that the light extraction effect similar to that of the micro lenses 154 can be additionally induced.

However, the embodiments of the disclosure are not limited thereto. Alternatively, the first, second, third, and fourth lens patterns 156a, 156b, 156c, and 156d can be rotated with different angles from the micro lenses 154 of the respective sub-pixels SP1, SP2, SP3, and SP4. For example, the first, second, third, and fourth lens patterns 156a, 156b, 156c, and 156d can be rotated with the fourth, third, second, and first angles a4, a3, a2, and a1, respectively. In this case, the light extraction can be further improved by scattering effects due to the first, second, third, and fourth lens patterns 156a, 156b, 156c, and 156d. Other variations are possible.

In some embodiments of the present disclosure, the first sub-pixel SP1 is shown to have at least one flat portion FP, while some other sub-pixels may or may not have at least one flat portion FP. Other variations are possible. For instance, in FIG. 3, the two flat portions FP can be disposed in the second sub-pixel SP2 only, in the third sub-pixel SP3 only, or in the fourth sub-pixel SP4 only, among the first to fourth sub-pixels SP1 to SP4.

In the organic light-emitting diode display device of the embodiments of the present disclosure, the plurality of micro lenses can be provided in the emission area of each sub-pixel, so the light extraction efficiency can be improved.

In addition, by placing the lens pattern in the flat portion of the emission area, the size of the opening of the bank can be accurately measured and managed. At the same time, the manufacturing of the micro lenses can be more efficiently managed and controlled. Specially, it is possible to manage the process for forming an optimal structure that can improve the light extraction efficiency through monitoring of the micro lenses. By using this configuration, the efficiency of the organic light-emitting diode display device can be improved, and the power consumption can be reduced due to the improved efficiency, thereby implementing the low power consumption.

Moreover, the production energy can be reduced and the process optimization can be achieved by the rework and process management through the monitoring. Furthermore, the production hazards and regulated substances can be reduced, and thus the aspects of the present disclosure can be helpful to encourage and improve recycling.

Additionally, by placing the lens pattern as close to the micro lenses in the opening as possible, the monitoring effect can be maximized, and the light extraction effect can be further improved due to light extraction by the lens patterns.

Further, the lens pattern can be provided in each sub-pixel, the micro lenses can be manufactured and managed more precisely for each sub-pixel.

In addition, by rotating the micro lenses with the different angles in the sub-pixels, respectively, a rainbow pattern and/or a circular ring pattern which can occur due to a regular arrangement can be prevented or minimized, thereby improving the image quality of the display device. In this case, by rotating or non-rotating the lens pattern, the light extraction effect can be improved.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. An organic light-emitting diode display device, comprising:
a plurality of sub-pixels disposed over a substrate, each sub-pixel having an emission area and a non-emission area;
a thin film transistor in the non-emission area of each sub-pixel;
an overcoat layer over the thin film transistor in each sub-pixel, and including a plurality of micro lenses in the emission area of each sub-pixel; and
a light-emitting diode in the emission area of each sub-pixel over the overcoat layer, and connected to the corresponding thin film transistor,
wherein for one sub-pixel among the plurality of sub-pixels, the emission area of the one sub-pixel has at least one flat portion disposed at the overcoat layer where a top surface of the overcoat layer is flat, and the overcoat layer has at least one lens pattern in the at least one flat portion.

2. The organic light-emitting diode display device of claim 1, wherein the at least one lens pattern has a same size and shape as at least one of the plurality of micro lenses.

3. The organic light-emitting diode display device of claim 2, wherein each of the plurality of micro lenses has a hexagonal shape in a top plan view, and a distance between the at least one lens pattern and one of the plurality of micro lenses adjacent thereto is equal to or greater than a side length of one micro lens among the plurality of micro lenses.

4. The organic light-emitting diode display device of claim 1, wherein a distance between the at least one lens pattern and one of the plurality of micro lenses adjacent thereto is greater than a distance between two adjacent micro lenses among the plurality of micro lenses.

5. The organic light-emitting diode display device of claim 1, wherein for the one sub-pixel, the at least one flat portion in the emission area includes two flat portions, and
wherein the two flat portions are disposed at opposing sides of the emission area and are disposed on a same straight line.

6. The organic light-emitting diode display device of claim 5, further comprising a bank having an opening corresponding to the emission area of the one sub-pixel,
wherein two side surfaces of the bank with the opening interposed therebetween and facing each other are disposed over part of the two flat portions, respectively.

7. The organic light-emitting diode display device of claim 1, wherein the plurality of sub-pixels include the one sub-pixel being a first sub-sub-pixel, a second sub-pixel, a third sub-pixel and a fourth sub-pixel, which are provided over the substrate along a one direction,
wherein the emission areas of the first, second, third, and fourth sub-pixels have at least one first, second, third, and fourth flat portions, respectively, and
wherein the overcoat layer has at least one first, second, third, and fourth lens patterns in the first, second, third, and fourth flat portions, respectively.

8. The organic light-emitting diode display device of claim 7, wherein at least one of the first, second, third, and fourth flat portions is disposed on a different straight line from another one of the first, second, third, and fourth flat portions.

9. The organic light-emitting diode display device of claim 7, wherein the plurality of micro lenses in the first, second, third, and fourth sub-pixels are rotated so that lines connecting centers of the plurality of micro lenses adjacent to each other have first, second, third, and fourth angles with respect to the one direction, respectively.

10. The organic light-emitting diode display device of claim 9, wherein the first, second, third, and fourth lens patterns are rotated at same angles as the plurality of micro lenses in the first, second, third, and fourth sub-pixels, respectively.

11. The organic light-emitting diode display device of claim 9, wherein the first, second, third, and fourth lens patterns are rotated at different angles from the plurality of micro lenses in the first, second, third, and fourth sub-pixels, respectively.

12. The organic light-emitting diode display device of claim 9, wherein each of the first, second, third, and fourth angles is greater than 0 degrees and is equal to or less than 60 degrees.

13. The organic light-emitting diode display device of claim 1, wherein the plurality of micro lenses in the emission area of at least some of the plurality of sub-pixels are rotated at an angle greater than 0 degrees to 60 degrees.

14. A display device, comprising:
a plurality of sub-pixels disposed over a substrate, each sub-pixel having an emission area and a non-emission area adjacent to the emission area;
an overcoat layer disposed over the substrate, and including a plurality of micro lenses in the emission area of each sub-pixel; and
a light-emitting element in the emission area of each sub-pixel and disposed over the plurality of micro lenses,
wherein the plurality of micro lenses in the emission area of at least one of the plurality of sub-pixels are rotated.

15. The display device of claim 14, wherein the plurality of micro lenses in the emission area of all of the plurality of sub-pixels are rotated.

16. The display device of claim 14, wherein in each of at least one of the plurality of sub-pixels, the emission area includes one or two flat portions having a top flat surface, and a lens pattern disposed in each of the one or two flat portions.

17. The display device of claim 16, wherein in the emission area of one of the plurality of sub-pixels:
the plurality of micro lenses and the lens pattern disposed in each of the one or two flat portions are rotated at a same angle.

18. The display device of claim 16, wherein the plurality of micro lenses in the emission areas of at least two of the plurality of sub-pixels are rotated at different angles, and
wherein the lens pattern disposed in each of the one or two flat portions for the at least two of the plurality of sub-pixels are respectively rotated at the same different angles.

19. The display device of claim 16, wherein a size and shape of one of the plurality of micro lenses are respectively same as a size and shape of the lens pattern.

20. The display device of claim 14, further comprising:
a color filter disposed below the light-emitting element and plurality of micro lenses in the emission area of each sub-pixel.
